(19) United States
(12) Patent Application Publication
(10) Pub. No.: US 2015/0155173 A1
(43) Pub. Date: Jun. 4, 2015

(54) METHOD FOR MANUFACTURING SEMICONDUCTOR DEVICE

(71) Applicant: CANON KABUSHIKI KAISHA, Tokyo (JP)

(72) Inventor: Katsunori Hirota, Yamato-shi (JP)

(21) Appl. No.: 14/559,729

(22) Filed: Dec. 3, 2014

(30) Foreign Application Priority Data
Dec. 4, 2013 (JP) 2013-251386

(51) Int. Cl. H01L 21/283; H01L 27/146; H01L 21/02

(52) U.S. Cl. CPC H01L 21/283; H01L 21/02164; H01L 21/0217; H01L 21/02271; H01L 27/14689

(57) ABSTRACT

A method includes a step of forming a side wall spacer covering a side surface of a gate electrode of a transistor by etching a first insulator film, and a step of forming a second insulator film covering an upper surface of the gate electrode, the side wall spacer and a source/drain region. The second insulator film is a multilayer film including a silicon oxide layer and a silicon nitride layer. The second step includes forming the silicon oxide layer by thermal CVD so as to come in contact with the side wall spacers, and forming the silicon nitride layer by plasma CVD so as to come in contact with the silicon oxide layer of the second insulator film.

### BACKGROUND OF THE INVENTION

1. Field of the Invention

The present application relates to a semiconductor device including an insulated-gate field-effect transistor.

2. Description of the Related Art

Japanese Patent Laid-Open No. 2008-252032 discloses a transistor covered with a silicon nitride film (UV-SiN) formed by plasma CVD using a UV light source and functioning as a hydrogen supplier.

### SUMMARY OF THE INVENTION

The present inventors, however, found that the transistor of Japanese Patent Laid-Open No. 2008-252032 has a problem with reliability. The reliability refers to that in noise characteristics and long-time reliability of the gate insulating film. Long-time reliability can be estimated by time-dependent dielectric breakdown (TDDB). Negative bias temperature instability (NBTI) may also be an index of long-time reliability.

To solve the problem with reliability, a method is provided for manufacturing a semiconductor device including an insulated-gate field-effect transistor. The method includes a first step of forming a side wall spacer covering a side surface of a gate electrode of the transistor by forming a first insulator film covering an upper and a side surface of the gate electrode and a source/drain region of the transistor, and etching the first insulator film, a second step of forming a silicide layer on the source/drain region, and a third step of forming a second insulator film including a silicon oxide layer and a silicon nitride layer so as to cover the side wall spacer and the silicide layer. The third step includes forming the silicon oxide layer of the second insulator film by thermal CVD so as to come in contact with the side wall spacer, and forming the silicon nitride layer of the second insulator film by plasma CVD so as to come in contact with the silicon oxide layer of the second insulator film.

Further features of the present invention will become apparent from the following description of exemplary embodiments with reference to the attached drawings.

### BRIEF DESCRIPTION OF THE DRAWINGS

FIG. 1A is a schematic plan view of a semiconductor device according to an embodiment, and FIG. 1B is a circuit diagram of the semiconductor device.

FIG. 2A is a plan view of a semiconductor device according to an embodiment, and FIG. 2B is a schematic sectional view of the semiconductor device.

FIG. 3 is a schematic fragmentary sectional view of a semiconductor device according to an embodiment.

FIGS. 4A to 4C are schematic sectional views illustrating a method for manufacturing a semiconductor device.

FIGS. 5A to 5C are schematic sectional views illustrating the method for manufacturing a semiconductor device.

FIGS. 6A to 6C are schematic sectional views illustrating the method for manufacturing a semiconductor device.

### DESCRIPTION OF THE EMBODIMENTS

Embodiments of the invention will now be described with reference to the drawings. In the following description and the drawings, the same reference numerals reference the same parts. The description of the same parts designated by the same reference numerals throughout the drawings may be omitted.

An image sensing device IS will be described as an embodiment of the semiconductor device of the present application.

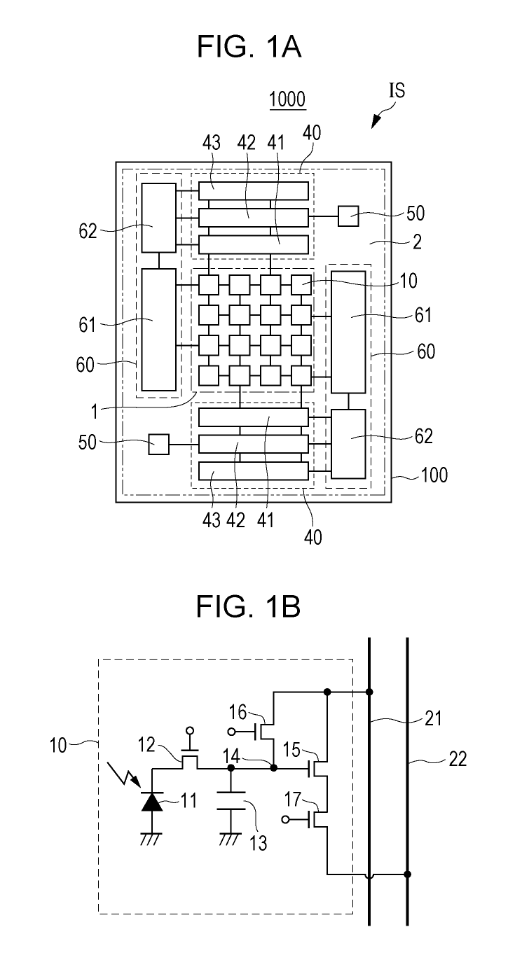

The semiconductor device 1000 shown in FIG. 1A includes a pixel circuit section 1 in which pixel circuits 10 are arranged 10, and a peripheral circuit section 2 in which peripheral circuits are arranged. The pixel circuit section 1 and the peripheral circuit section 2 are disposed on the same silicon substrate 100. In FIG. 1A, the pixel circuit section 1 is surrounded by a dotted chain line, and the peripheral circuit section 2 is the region between the dotted chain line and a double dotted chain line. The peripheral circuit section 2 lies around the pixel circuit section 1, that is, between the pixel circuit section 1 and the edges of the silicon substrate 100. Although FIG. 1A shows an area sensor in which a plurality of pixel circuits 10 are two-dimensionally arranged, the semiconductor device may be a linear sensor in which the pixel circuits 10 are linearly arranged.

FIG. 1B is a circuit diagram of one of the pixel circuits 10. The pixel circuit 10 includes a photoelectric conversion element 11, a transfer element 12, a capacitor 13, an amplifying element 15, a reset element 16, and a selection element 17. In the present embodiment, the photoelectric conversion element 11 is a photodiode, and the amplifying element 15, the reset element 16 and the selection element 17 are transistors.

The transistors of the pixel circuit are referred to as pixel transistors. The amplifying element 15, the reset element 16 and the selection element 17 are insulated-gate field-effect transistors. Insulated-gate semiconductor field-effect transistors are generally called MISFET (Metal-insulator-semiconductor field-effect transistor). Although the MOSFETs used in the present embodiment are metal-oxide-semiconductor field-effect transistors (MOSFET), whose gate insulating film is made of an oxide film, the gate insulating film is not limited to an oxide film. The gate insulating film may be made of pure silicon oxide or pure silicon nitride. Alternatively, the gate insulating film may be other oxide films having a high dielectric constant (k) such as hafnium oxide, that is, what is called high-k gate insulating film. The transfer element 12 is a MOS gate, and thus a transistor may be defined by the transfer element 12 as the gate, the photoelectric conversion element 11 as the source, and the capacitor 13 as the drain.

In the present embodiment, the pixel transistors are each MOSFET (nMOSFET) including an n-type channel (inversion layer) in the present embodiment. However, in an embodiment, some of the pixel transistors may be p-channel MOSFETs (pMOSFETs). Other transistors than the insulated-gate field-effect transistor may be used in the pixel circuit 10. For example, the amplifying element 15 may be a junction field-effect transistor (JFET) or a bipolar transistor. In the following description, a first conductivity type refers to the conductivity type in which charges used as signal charges in a pixel circuit are majority carriers, and a second conductivity type refers to the conductivity type in which charges used as signal charges are minority carriers. When electrons are used as the signal charges, the first conductivity type is n-type, and the second conductivity type is p-type.

The transfer element 12 transfers signal charges generated in the photoelectric conversion element 11 to the capacitor 13. The capacitor 13 transmits to a node 14 a voltage according to the capacitance thereof and the amount of the signal charges. The gate of the amplifying element 15 is connected to the capacitor 13 via the node 14; the drain of the amplifying element 15 is connected to a power supply line 21 via the selection element 17; and the source of the amplifying element 15 is connected to an output line 22 via the selection element 17. The capacitor 13 and the gate of the amplifying element 15 are connected to the power supply line 21 via the reset element 16. By bringing the reset element 16 into ON, the potential of the node 14 is reset to a potential according to the potential of the power source. Also, by bringing the selection element 17 into ON, a signal according to the potential of the node 14 is output from the amplifying element 15 to the output line 22. The configuration of the pixel circuit section 1 may be modified as required.

As shown in FIG. 1A, the peripheral circuit section 2 may include a signal processing unit 40 configured to process electrical signals generated in the pixel circuits 10. In addition to the signal processing unit 40, the peripheral circuit section 2 may include an output unit 50 configured to output signals processed in the signal processing unit 40, and a control unit 60 configured to control the pixel circuits 10 and the signal processing unit 40. Circuits constituting the signal processing unit 40, the output unit 50 or the control unit 60 are collectively referred to as peripheral circuits.

In the present embodiment, the signal processing unit 40 includes an amplifier circuit 41 including a plurality of column amplifiers, a conversion circuit 42 including a plurality of column AD converters, and a horizontal scanning circuit 43 configures to select an output signal from the conversion circuit 42 and output the signal to the output unit 50. The signal processing unit 40 may be designed so as to be capable of correlated double sampling (CDS), parallel-serial conversion, analog-digital conversion, and the like. The output unit 50 includes an electrode pad and a protection circuit, and the control unit 60 includes a vertical scanning circuit 61 and a timing generation circuit 62. The configuration of the peripheral circuit section 2 may be modified as required.

The peripheral circuits each may include a plurality of insulated-gate field-effect transistors, and particularly may be a complementary MOS (CMOS) circuit including an nMOSFET and a pMOSFET. The transistors of the peripheral circuits are referred to as peripheral transistors, and may be referred to as a peripheral nMOSFET or a peripheral pMOSFET for specifying the conductivity type. The peripheral circuit also includes passive elements such as a resistive element and a capacitor element, as well as active elements such as a transistor and a diode.

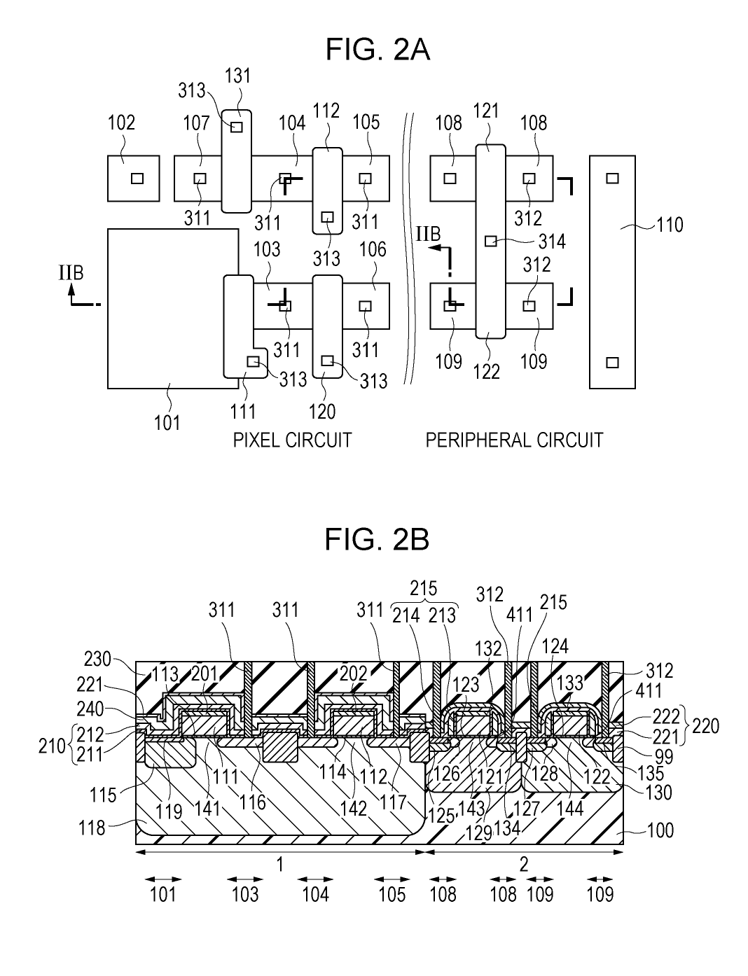

The structure of the semiconductor device will be further described in detail with reference to FIGS. 2A and 2B. FIG. 2A is a schematic plan view illustrating a pixel circuit 10 in the peripheral circuit section 1 and part of the peripheral circuit section 2.

FIG. 2A shows a light-receiving region 101 of the photoelectric conversion element 11, a detection region 103 including the capacitor 13 and configured to detect charges, and a drain region 106 of the reset element 16. FIG. 2A also shows the drain region 105 of the amplifying element 15, the source region 104 of the amplifying element 15, and the source region 107 of the selection element 17. The detection region 103 doubles as the source region of the reset element 16, and the source region 104 of the amplifying element 15 doubles as the drain region of the selection element 17. In the following description, the region that is either the source or the drain region of an insulated-gate field-effect transistor is collectively referred to as a source/drain region. Also, FIG. 2A shows source/drain regions 108 of a peripheral nMOSFET and source/drain regions 109 of a peripheral pMOSFET.

FIG. 2A further shows the gate electrode 111 of the transfer element 12, the gate electrode 120 of the reset element 16, the gate electrode 112 of the amplifying element 15, and the gate electrode 131 of the selection element 17. Also, FIG. 2A shows the gate electrode 121 of the peripheral nMOSFET and the gate electrode 122 of the peripheral pMOSFET. Each gate electrode is defined by a polysilicon layer made of a polysilicon (polycrystalline silicon). Although the gate electrodes 121 and 122 are formed in one body in the present embodiment, they may be separate in an embodiment.

FIG. 2A also shows a reference contact region 102 of the pixel circuit 10. The reference contact region 102 is provided with a reference contact for supplying the reference potential (for example, ground potential) of the pixel circuit 10 through a conductive line. By providing a plurality of reference contact regions 102 in the pixel circuit section 1, the variation in potential of the pixel circuit section 1 can be suppressed, and thus images is prevented from being shaded.

FIG. 2A also shows a resistive element 110 of the peripheral circuit. The resistive element 110 is provided with contacts at both ends in the impurity region thereof to have a resistance according to the distance between the contacts. Although the impurity region of the resistive element 110 is n-type in the present embodiment, it may be p-type. Alternatively, a resistive element 110 having an n-type impurity region and a resistive element having a p-type impurity region may be used in combination. The peripheral circuit section 2 may include other passive elements. For example, such passive elements include a capacitor having a MOS structure made of a polysilicon layer material, and a resistive element made of a polysilicon layer material.

The light-receiving region 101, the detection region 103, the source/drain regions of the pixel transistors, and the source/drain regions 108 of the peripheral nMOSFET are all n-type impurity regions. The source/drain regions 109 of the peripheral pMOSFET are p-type impurity regions.

FIG. 2B is a sectional view of the semiconductor device taken along line IIB-IIB in FIG. 2A. The silicon substrate 100 is divided into a plurality of active regions by element isolation regions. The element isolation regions are element isolation insulators 99 formed by a shallow trench isolation process (STI), local oxidation of silicon (LOCOS) that is an isolation process by selective oxidation, or the like. Each active region is provided with an impurity region, and the impurity region acts as a semiconductor element. The element isolation region may be provided with a p-type impurity region (not shown) for dividing the PN junction.

The active regions of the silicon substrate 100 are each provided with a well having the conductivity type according to the conductivity type of the semiconductor element. The pixel circuit section 1 is provided with a p-type well 118, and the peripheral circuit section 2 is provided with a p-type well 129 and an n-type well 130. The reference contact region 102 shown in FIG. 2A is provided with a p-type impurity region (not shown) having a higher impurity concentration than the p-type well 118. The reference potential is supplied to the p-type well 118 via this impurity region through the conductive line connected to the reference contact region 102.

The sectional structure of the pixel circuit section 1 will now be described. The light-receiving region 101 is provided with an n-type accumulation area 115 of the photoelectric conversion element 11 therein, and a p-type surface area 119 is formed to bury the light-receiving element between the accumulation area 115 and the surface of the silicon substrate 100, thereby enabling the light-receiving element to act as a photodiode. The detection region 103 is provided with an impurity region 116 for the capacitor 13. This impurity region 116 is a floating diffusion region. The source/drain regions of the amplifying element 15, the reset element 16 and the selection element 17 are each provided with an n-type impurity region 117. Although FIG. 2B shows only the cross-section of the amplifying element 15, the same structure applies to the reset element 16 and the selection element 17.

The gate electrodes 111 and 112 disposed on the silicon substrate 100 with the gate insulating films 113 and the gate insulating film 114 therebetween are covered with insulator members 201 and 202 made of silicon oxide or silicon nitride, respectively. In the present embodiment, the gate insulating films 113 and 114 and the gate insulating films of the other elements of the pixel circuit 10 are mainly made of silicon oxide, and a small amount (less than 10%) of nitrogen is added to the silicon oxide by plasma nitridation or thermal nitridation. The nitrogen-containing silicon oxide has higher dielectric constant than pure silicon oxide, and accordingly increases the performance of transistors. It should however be appreciated that the gate insulating films may be made of pure silicon oxide or pure silicon nitride. Alternatively, the gate insulating film may be other oxide films having a high dielectric constant (k) such as hafnium oxide, that is, what is called high-k gate insulating film.

A first insulator film 210 covers the upper surfaces of the gate electrodes 111 and 112 with the corresponding insulator member 201 or 202 therebetween and further covers the side surfaces of the gate electrodes 111 and 112. The first insulator film 210 also covers the upper surfaces of the gate electrodes 120 and 131 with an insulator member therebetween and further covers the side surfaces of the gate electrodes 120 and 131. Furthermore, the first insulator film 210 covers the light-receiving region 101, the detection region 103, and the source/drain regions of the amplifying element 15, the reset element 16 and the selection element 17.

The first insulator film 210 is a multilayer composite including a lower first silicon oxide layer 211 and an upper first silicon nitride layer 212. The first silicon oxide layer 211 and the first silicon nitride layer 212 are in contact with each other to form an interface. In the present embodiment, the first silicon oxide layer 211 is in contact with the side surfaces of the gate electrodes 111, 112, 120 and 131. However, the first silicon oxide layer 211 may be separated from the gate electrodes 111, 112, 120 and 131 by another layer. Furthermore, in the present embodiment, the first silicon oxide layer 211 is in contact with the light-receiving region 101, the detection region 103, and the source/drain regions of the amplifying element 15, the reset element 16 and the selection element 17 to form interfaces with the silicon substrate 100. However, the first silicon oxide layer 211 and the silicon substrate 100 may be separated from each other by another layer in an embodiment.

The first silicon oxide layer 211 has a refractive index of about 1.5, and the first silicon nitride layer 212 has a refractive index of about 2.0. The first insulator film 210 including such silicon oxide and silicon nitride layers can be used as an antireflection film to block light coming to the first light-receiving region 101 by covering the light-receiving region 101. For higher antireflection performance, the first silicon nitride layer 212 desirably has a larger thickness than the first silicon oxide layer 211. This is because silicon nitride has a higher refractive index than silicon oxide.

The first insulator film 210 is covered with a protective film 240. The protective film 240 is an insulating monolayer film or multilayer composite including a silicon oxide layer or a silicon nitride layer. The protective film 240 is covered with a second silicon oxide layer 221. The second silicon oxide layer 221 is covered with a third insulator film 230. The third insulator film 230 is made of, for example, silicate glass such as borophosphosilicate glass (BPSG), borosilicate glass (BSG) or phosphosilicate glass (PSG), or silicon oxide. The upper surface of the third insulator film 230 is planarized so as substantially not to be affected by the uneven surface of the underlying second silicon oxide layer 221.

Conductor members 311 are connected to the source/drain regions of the amplifying element 15, the reset element 16 and the selection element 17 through the third insulator film 230, the second silicon oxide layer 221, the protective film 240 and the first insulator film 210. The conductor members 311 are each a contact plug mainly made of, for example, tungsten. Similarly, conductor members 313 (see FIG. 2A) are connected, one each, to the gate electrodes 111, 112, 120 and 131. The conductor members 313 are connected to the gate electrodes 111 and 112 through the third insulator film 230, the second silicon oxide layer 221, the protective film 240, the first insulator film 210 and the insulator member 201 or 202.

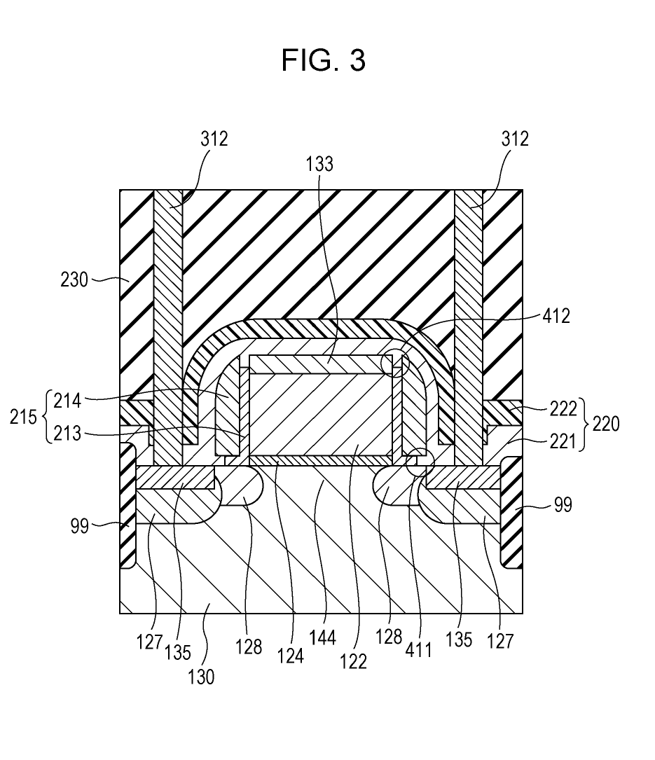

The sectional structure of the peripheral circuit section 2 will now be described. FIG. 3 is an enlarged view of a peripheral pMOSFET. The following description refers to FIGS. 2A and 2B and 3 together. The source/drain regions 108 of the peripheral nMOSFET are each provided with an n-type heavily doped impurity region 125, an n-type lightly doped impurity region 126, and a silicide layer 134. The silicide layer 134 covers the heavily doped impurity region 125. The heavily doped impurity region 125 has a higher impurity concentration than the lightly doped impurity region 126. The source/drain regions 109 of the peripheral pMOSFET are each provided with a p-type heavily doped impurity region 127, a p-type lightly doped impurity region 128, and a silicide layer 135. The heavily doped impurity region 127 has a higher impurity concentration than the lightly doped impurity region 128. The silicide layer 135 covers the heavily doped impurity region 127. These peripheral transistors each have a lightly doped drain (LDD) structure including a highly doped impurity region 125 or 127 and a highly doped impurity region 126 or 128.

The gate electrodes 121 and 122 are disposed on the silicon substrate 100 with a gate insulating film 123 or 124 therebetween. In the present embodiment, as with the gate insulating films of the pixel transistors of the pixel circuit 10, the gate insulating films 123 and 124 are mainly made of silicon oxide, and a small amount (less than 10%) of nitrogen is added to the silicon oxide by plasma nitridation or thermal nitridation. The thicknesses of the gate insulating films 123 and 124 of the peripheral transistors are smaller than those of the gate insulating films 113 and 114 of the pixel transistors. For example, the gate insulating films 113 and 114 have thicknesses in the range of 5.0 nm to 10 nm, while the gate insulating films 123 and 124 have thicknesses in the range of 1.0 nm or more and less than 5.0 nm. This structure ensures that the pixel MOSFETs have high resistance to voltage and that the peripheral MOSFETs have high driving speed. The gate electrodes 121 and 122 include silicide layers 132 and 134, respectively, as the uppermost layer.

Thus, the peripheral transistors have self-aligned silicide (salicide) structures, each including the silicide layers 132 or 133 and 134 or 135. The metal components in the silicide layers in a salicide structure include titanium, nickel, cobalt, tungsten, molybdenum, tantalum, chromium, palladium, and platinum.

The side surfaces of the gate electrodes 121 and 122 of the peripheral transistors are covered with side wall spacers 215 made of an insulator. The side wall spacers 215 also cover the lightly doped impurity regions 126 and 128 of the source/drain regions 108 and 109. Each side wall spacer 215 has a multilayer structure including a silicon oxide layer 213 and a silicon nitride layer 214. The silicon oxide layer 213 is disposed between the silicon nitride layer 214 and the gate electrode 121, between the silicon nitride layer 214 and the gate electrode 122, between the silicon nitride layer 214 and the source/drain regions 108, and between the silicon nitride layer 214 and the source/drain region 109. The silicon oxide layer 213 and the silicon nitride layer 214 are in contact with each other to form an interface.

The second insulator film 220 covers the upper surfaces of the gate electrodes 121 and 122, side wall spacers 215, and the source/drain regions 108 and 109. The second insulator film 220 has a multilayer structure including a second silicon oxide layer 221 and a second silicon nitride layer 222. The second silicon oxide layer 221 and the second silicon nitride layer 222 are in contact with each other to form an interface.

The second silicon oxide layer 221 is disposed between the silicon nitride layers 214 of the side wall spacers 215 and the second silicon nitride layer 222. Each silicon nitride layer 214 and the second silicon nitride layer 221 are in contact with each other to form an interface. Hence, the side wall spacers 215 and the second insulator film 220 form interfaces.

The second insulator film 220 covers the heavily doped impurity regions 125 and 127 of the source/drain regions 108 and 109. The second insulator film 220 also covers the silicide layers 134 and 135 of the source/drain regions 108 and 109. In the present embodiment, the second silicon oxide layer 221 of the second insulator film 220 forms interfaces with each of the silicide layers 134 and 135. However, the silicide layers 134 and 135 need not be provided. In this instance, the second silicon oxide layer 221 may form interfaces with each of the heavily doped impurity regions 125 and 127.

The first silicon nitride layer 212 is formed by thermal CVD, and the second silicon nitride layer 222 is formed by plasma CVD. This will be described in detail later. The first silicon nitride layer 212 is denser than the second silicon nitride layer 222. The second silicon nitride layer 222, which is coarser than the first silicon nitride layer 212, has a higher permeability to hydrogen than the first silicon nitride layer 212. The second silicon nitride layer 222 contains hydrogen with a higher content than the first silicon nitride layer 212. The second silicon nitride layer 222 rich in hydrogen can function as a hydrogen supplier.

Conductor members 312 are connected to the source/drain regions 108 and 109 of the peripheral transistors through the third insulator film 230 and the second insulator film 220. The conductor members 312 are each a contact plug mainly made of, for example, tungsten. Similarly, conductor members 314 (see FIG. 2A) are connected, one each, to the gate electrodes 121 and 122.

The conductor members 311, 312, 313 and 314 are connected to a wiring layer (not shown) mainly made of aluminum or copper and disposed on the third insulator film 230. A plurality of wiring layers may be disposed on one another with interlayer insulating layers therebetween.

The light-receiving surface of the silicon substrate 100 is provided with a microlens array or a color filter array right above the wiring layers. The semiconductor device 1000 may include a chip including the silicon substrate 100, and a package containing the chip. The semiconductor device 1000 may be used as an image sensing device in an image sensing system such as a camera or an information terminal.

The semiconductor device 1000 of the present embodiment used as an image sensing device IS may be of a front surface emission type having a light-receiving surface at the main surface of the silicon substrate 100 having the gate electrodes 111, 112, 121 and 122 and the wiring layer (not shown). Alternatively, the semiconductor device 1000 may be of a rear surface emission type having a light receiving surface at the main surface of the silicon substrate 100 opposite the gate electrodes 111, 112, 121 and 122 and the wiring layer (not shown). However, the semiconductor device 1000 of the present embodiment is suitable for an image sensing device of a front surface emission type. This is because the layers overlying the light-receiving region 101 are suitable for forming an antireflection structure.

In the enlarged view of a peripheral pMOSFET in FIG. 3, the silicon oxide layer 213 of each side wall spacer 215 may fail to fill the entire region between the source/drain region 109 and the silicon nitride layer 214 under the side wall spacer 215, and thus a defective region 411 may be formed at the lower end of the side wall spacer 215. More specifically, such defective regions 411 are often formed between the silicon nitride layer 214 and the lightly doped impurity regions 128 or between the silicon nitride layer 214 and the silicide layers 134 and 135. As shown in FIG. 3, however, the defective regions 411 are filled with the second silicon oxide layer 221 of the second insulator film 220 between the source/drain regions 109 and the silicon nitride layer 214. Also, the silicon oxide layer 213 of the side wall spacers 215 may fail to fill the entire regions between the gate electrode 122 and the silicon nitride layer 214, and thus defective regions 412 may be formed at the upper ends of the side wall spacers 215. As shown in FIG. 3, however, the defective regions 412 are filled with the second silicon oxide layer 221 of the second insulator film 220. Such defective regions or gaps are present in the peripheral nMOSFETs as well as the peripheral pMOSFETs. More specifically, such gaps are formed between the side wall spacers 215 and the source/drain regions 108 and between the side wall spacers 215 and the gate electrode 121, and are filled with the second silicon oxide layer 221 of the second insulator film 220.

The structure described above can improve the reliability of semiconductor devices including the semiconductor device 1000. The reason is as bellow.

If the defective regions 411 are vacant or contain part of a silicon nitride layer, the TDDB properties of the gate insulating films of the peripheral nMOSFETs and pMOSFETs are degraded. Also, noise is caused by carrier exchange between the channels and the interface state caused by dangling bonds at the surface of the silicon substrate 100 and results in degraded noise characteristics of the peripheral nMOSFETs and pMOSFETs. In addition, the interface state causes NBTI in the peripheral pMOSFETs. In particular, when the gate insulating film is made of nitrogen-containing silicon oxide or silicon nitride, the nitrogen causes the energy gap of the gate insulating film to have a level, and thus the peripheral pMOSFETs are considerably affected by the interface state.

By filling the defective regions 411 by the second silicon oxide layer 221, TDDB properties are improved. Also, hydrogen may be supplied to the surface of the silicon substrate 100 from or through the second silicon nitride layer 222 so as to terminate the dangling bonds, thereby reducing noise and NBTI. In this instance, silicon oxide is more permeable to hydrogen than silicon nitride and unlikely to interfere with hydrogen supply. In addition, the silicon nitride layers 214 of the side wall spacers 215 less permeable to hydrogen than the silicon oxide layer 213 act as diffusion barriers of hydrogen and limit hydrogen supply to the path through the silicon oxide layer 213, thereby efficiently supplying hydrogen to the channel regions 143 and 144. Furthermore, since the second silicon oxide layer 221 is disposed between the second silicon nitride layer 222 and the source/drain regions 108 and 109, stress produced between silicon and silicon nitride or between silicide and silicon nitride is reduced.

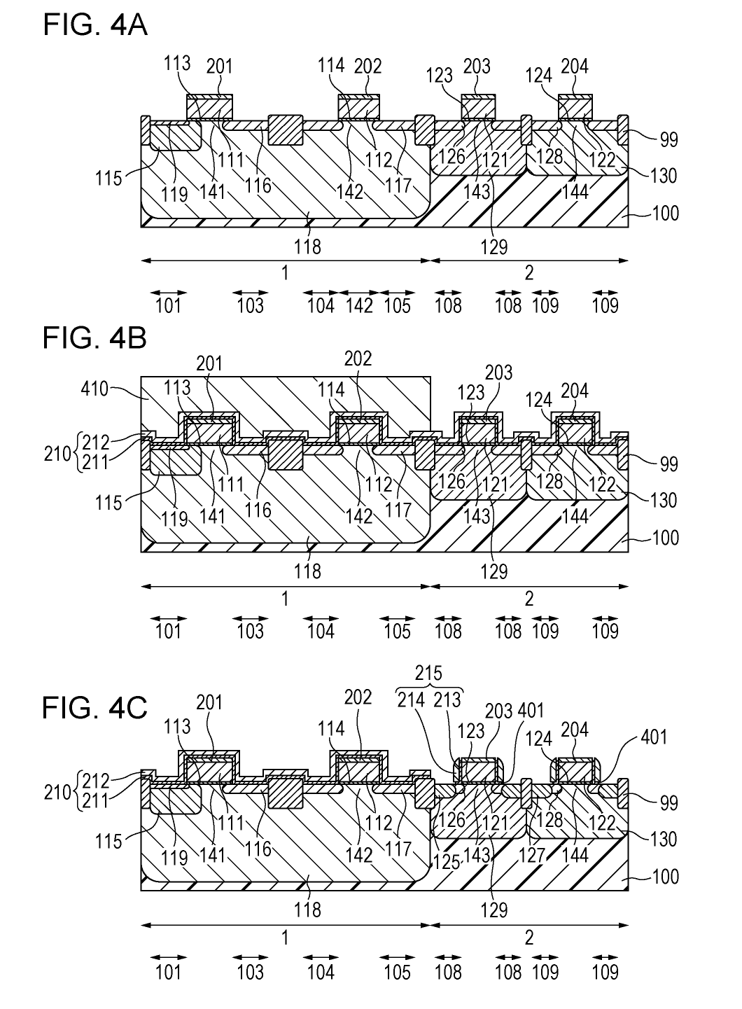

A method for manufacturing the semiconductor device 1000 will now be described with reference to FIGS. 4A to 6C. FIGS. 4A to 6C are sectional views illustrating a process for producing the semiconductor device 1000 up to the step shown in section in FIG. 2B. FIGS. 4A to 6C illustrate the pixel circuit section 1 and the peripheral circuit section 2 close to each other.

Referring now to FIG. 4A, Step A will first be described. In Step A, transistors will be formed.

In Stage A-1 of Step A, element isolation insulators 99 are formed in the silicon substrate 100 by STI or LOCOS. The silicon substrate 100 may be a silicon wafer cut from a silicon ingot, or a silicon wafer provided with a monocrystalline silicon layer thereon by epitaxial growth.

In subsequent Stage A-2, second conductivity type (p-type) wells 118 and 129 and a first conductivity type (n-type) well are formed.

In subsequent Stage A-3, a polysilicon film is formed on the silicon substrate 100 with a gate insulating film therebetween and is then doped according to the positions and conductivity types of the transistors. Then, insulator members 201, 202, 203 and 204 acting as hard masks are formed on the polysilicon film, and the polysilicon film is patterned using the insulator members 201, 202, 203 and 204 as masks. Thus, n-type gate electrodes 111, 112 and 121 and a p-type gate electrode 122 are formed.

In subsequent Stage A-4, an n-type accumulation area 115 and a p-type surface area 119 are formed. In addition, in Stage A-4, an impurity region 116 of the detection region and an n-type impurity region 117 for a single drain structure of the pixel circuit section 1 are formed in the source/drain regions. In Stage A-4, furthermore, lightly-doped impurity regions 126 and 128 are formed for the LDD structure of the peripheral circuit section 2. For forming the impurity regions 116 and 117 of the pixel circuit 10, the appropriate dosage is in the range of 5×10¹² to 5×10¹⁴ (ions/cm²), and is preferably in the range of 1×10¹³ to 1×10¹⁴ (ions/cm²). For forming the lightly doped impurity region 126 for the LDD structure, the appropriate dosage is in the range of 5×10¹² to 5×10¹⁴ (ions/cm²), and is preferably in the range of 1×10¹³ to 1×10¹⁴ (ions/cm²). Ion implantation for the n-type impurity regions 116 and 117 and ion implantation for the n-type impurity region 126 may be simultaneously performed using the same mask.

Step B will be described with reference to FIG. 4B. In Step B, a first insulator film 210 will be formed as shown in FIG. 4B. The first insulator film 210 covers the upper surfaces and side surfaces of the gate electrodes 111, 112, 121 and 122, the source/drain regions 103, 104, 105, 108 and 109 and the light-receiving region 101. Since the source/drain regions have been provided with the impurity regions 116, 117, 126 and 128 therein in Step A, the first insulator film 210 covers these impurity regions 116, 117, 126 and 128.

The first insulator film 210 has a multilayer structure including a first silicon oxide layer 211 and a first silicon nitride layer 212. The first silicon nitride layer 212 is formed so as to come in contact with the first silicon oxide layer 211. The formation of the first insulator film 210 includes Stage B-1 of forming the first silicon oxide layer 211 by thermal chemical vapor deposition (thermal CVD), and Stage B-2 of forming the first silicon nitride layer 212. Desirably, the first silicon nitride layer 212 is formed to a larger thickness than the previously formed first silicon oxide layer 211. The thickness of the first silicon nitride layer 212 may be twice or more that of the first silicon oxide layer 211. The thickness of the first silicon oxide layer 211 is, for example, in the range of 5 nm to 20 nm, and the thickness of the first silicon nitride layer 212 is, for example, in the range of 20 nm to 100 nm. In Stage B-1, the first silicon oxide layer 211 is formed by, for example, thermal CVD under the condition where the pressure (forming pressure) of the process gas containing tetraethoxysilane (TEOS) or the like as the source gas is in the range of 20 Pa to 200 Pa (what is called low-pressure CVD (LP-CVD)). The process gas refers to the entirety of the gases in the chamber including the source gas and optionally added carrier gas, and the forming pressure refers to the pressure of the process gas (total pressure). The deposition temperature (substrate temperature) at this time is, for example, in the range of 500° C. to 800° C. In Stage B-2, the first silicon nitride layer 212 is formed by, for example, thermal CVD under the condition where the pressure (forming pressure) of the process gas containing, for example, NH₃ and SiH₂Cl₂ as the source gas is in the range of 20 Pa to 200 Pa (what is called LP-CVD). The deposition temperature (substrate temperature) at this time is, for example, in the range of 500° C. to 800° C.

Step C will be described with reference to FIGS. 4B and 4C. In Step C, side wall spacers 215 will be formed. In Stage C-1 of Step C, a resist 410 is formed on the first insulator film 210, as shown in FIG. 4B. The resist 410 covers at least the light-receiving region 101 of the pixel circuit section 1 in such a manner that the peripheral circuit section 2 is open. The resist 410 also covers the source/drain regions 103, 104 and 105.

In subsequent Stage C-2, the first insulator film 210 is subjected to etching (etch back) using the resist 410 as a mask. Thus, side wall spacers 215 covering the side surfaces of the gate electrodes 121 and 122 in the peripheral circuit section 2 are formed as shown in FIG. 4C. Each side wall spacer 215 has a multilayer structure including a silicon oxide layer 213 and a silicon nitride layer 214. The silicon oxide layer 213 of the side wall spacer 215 is part of the remaining first silicon nitride layer 211, and the silicon nitride layer 214 of the side wall spacer 215 is part of the remaining first silicon nitride layer 212. The impurity regions 126 and 128 are exposed by the etching of the first insulating layer 210.

In this etching, to ensure that the impurity regions 126 and 128 are exposed at all the peripheral transistors of the silicon substrate 100, it is effective to perform ever-etching on the first silicon nitride layer 212 and the first silicon oxide layer 211. At this time, the gate insulating film and the first silicon oxide layer 211 are side-etched, and thus gaps 401 can be formed at the lower ends of the silicon nitride layers 214 of the side wall spacers 215. These gaps 401 result in the above-described defective regions 411. Also, gaps resulting in defective regions 412 can be formed between the silicon nitride layer 214 and the gate electrodes. Gaps 401 to be formed when the impurity regions 126 and 128 are exposed by the etching of the first insulator film 210 can be prevented by controlling the etching conditions.

In Stage C-2, the first insulator film 210 is further etched to be removed from the region (resistor forming region), other than the source/drain regions 108 and 109, where the resistive element shown in FIG. 2A will be formed.

The resist 410 covering the light-receiving region 101 allows the first insulator film 210 to remain over the light-receiving region 101 in Stage C-2. Consequently, damage to the photoelectric conversion element 11 can be reduced, and accordingly, noise generated in the photoelectric conversion element 11 can be reduced. The resist 410 covering the gate electrodes 111 and 112 allows the first insulator film 210 to remain over the channel regions 141 and 142 in Stage C-2. Consequently, damage to the amplifying element 15 can be reduced, and accordingly, noise generated in the transfer element 12 and the amplifying element 15 can be reduced.

Step A will be further described with reference to FIG. 4C. Heavily doped impurity regions 125 and 127 self-aligned with the side surfaces of the side wall spacers 215 are formed through Stages A-5 and A-6. In Agate A-5, a resist is formed to cover the pixel circuit section 1 and the peripheral pMOSFET, and n-type impurity ions are implanted using the gate electrode 121 and the side wall spacers 215 as a mask. Thus, the impurity regions 125 of the peripheral nMOSFET are formed. In Stage A-6, a resist is formed to cover the pixel circuit section 1 and the peripheral nMOSFET, and p-type impurity ions are implanted using the gate electrode 122 and the side wall spacers 215 as a mask. Thus, the impurity regions 127 of the peripheral pMOSFET are formed. Either Stage A-5 or A-6 may be first performed. For forming the heavily doped impurity regions 125 and 127 for LDD structures, the appropriate dosage is in the range of 5×10¹⁴ to 5×10¹⁶ (ions/cm²), and is preferably in the range of 1×10¹⁵ to 1×10¹⁶ (ions/cm²). Hence, in comparison between the formations of impurity regions having the same conductivity type, the dosage for forming the heavily doped impurity regions 125 and 127 is higher than the dosage for forming the lightly doped impurity regions 126 and 128. Also, the impurity concentration in the impurity regions 125 and 127 is higher than the impurity concentration in the impurity regions 126 and 128.

In at least one of Stages A-5 and A-6, impurity is implanted in the resistor forming region to form the resistive element 110 as diffusion resistance, simultaneously with the ion implantation for forming the impurity regions 125 or 127. The dosage for forming the impurity regions 125 and 127 is suitable for forming the impurity regions of the resistive element 110. On the other hand, the dosage for forming the impurity regions 126 and 128 is too low in terms of impurity concentration to reduce the resistance of the resistive element 110 to a practical level. By removing the first insulator film 210 from the resistor forming region in Stage C-5, ion implantation in Stage A-5 or A-6 becomes possible.

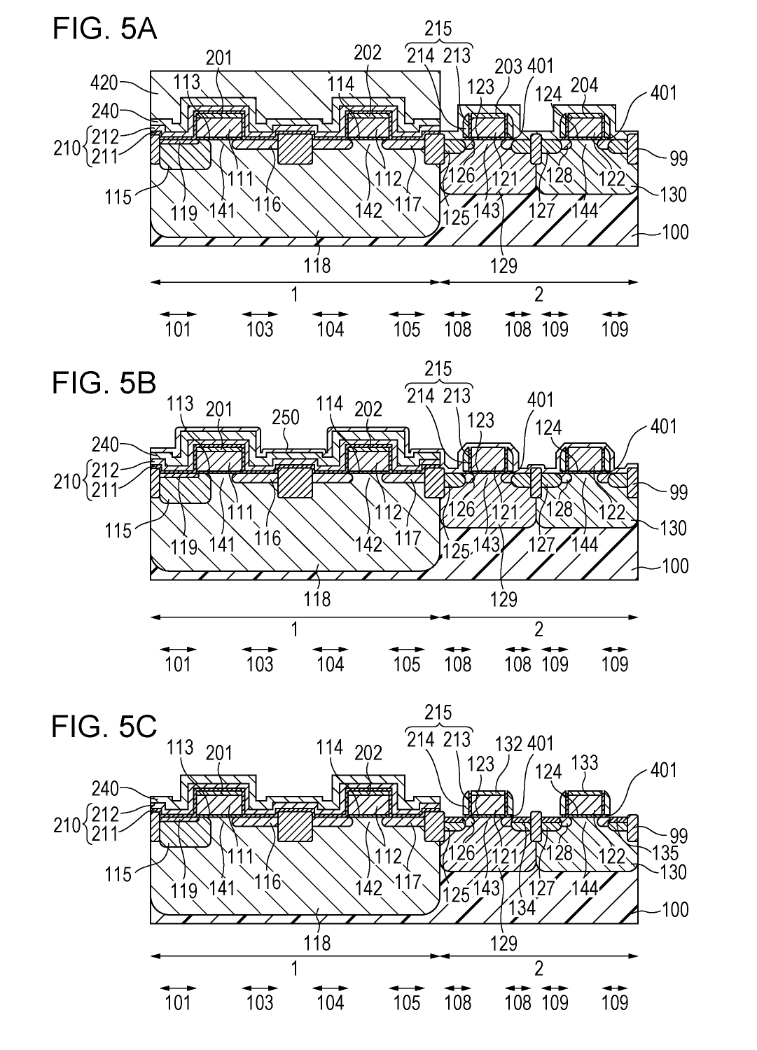

Step D will be described with reference to FIGS. 5A and 5B. In Step D, a protective film 240 will be formed.

In Stage D-1, first, a protective film 240 is formed to cover the source/drain regions 108 and 109, the gate electrodes 121 and 122, and the pixel circuit section 1, as shown in FIG. 5A. The protective film 240 has a thickness, for example, in the range of 30 nm to 130 nm. In subsequent Stage D-2, a resist 420 covering the pixel circuit section 1 is formed on the protective film 240.

In subsequent Stage E-3, the protective film 240 is etched using the resist 420 as a mask, thereby removing the portions of the protective film 240 overlying the source/drain regions 108 and 109 and the gate electrodes 121 and 122. At this time, the portion of the protective film 240 overlying the pixel circuit section 1 is left. The portion of the protective film 240 overlying the resistor forming region is also left. Subsequent to the etching of the protective film 240, the insulator members 203 and 204 covering the upper surfaces of the gate electrodes 121 and 122 are removed. If the protective film 240 is made of silicon oxide, the silicon oxide layer 213 of the side wall spacers is etched as the protective film 240 is etched, and thus gaps 401 can become larger. Also, the etching performed longer time to remove the silicon oxide insulating members 203 and 204 can cause the gaps 401 to increase in size. After the completion of the etching of the protective film 240, the resist 420 is removed.

Step E will be described with reference to FIG. 5B. In Step E, a metal film 250 will be formed to cover the source/drain regions 108 and 109 and the upper surfaces of the gate electrodes 121 and 122. The metal film 250 includes a metal layer made of a metal capable of silicidation. This metal layer is formed so as to come in contact with the source/drain regions 108 and 109 and the upper surfaces of the gate electrodes 121 and 122. The metal layer is also formed so as to come in contact with the protective film 240. The metal film 250 covers the portions of the protective film 240 remaining in the pixel circuit section 1 and the resistor forming region. The metal film 250 may be a multilayer composite further including a metal compound layer for preventing the oxidation of the metal layer. The metal layer may be made of cobalt, and the metal compound layer may be made of titanium nitride.

Step F will be described with reference to FIG. 5C. In Step F, silicide layers 134, 135, 132 and 133 will be formed. Step F may include Stages F-1 to F-4.

In Stage F-1, the silicon substrate 100 is heated to about 500° C. to allow the metal film 250 to react with the portions in contact with the metal film 250: source/drain region 108 and 109; and the gate electrodes 121 and 122. Thus silicide layers 132, 133, 134 and 135 are formed in a monosilicide state. In Stage F-2, the unreacted portion of the metal layer on the protective film 240 and the metal compound layer of the metal film 250 are removed. In Stage F-3, the silicon substrate 100 is further heated to a temperature higher than in Stage F-1, about 800° C., so that the monosilicide of the silicide layers 132, 133, 134 and 135 reacts into disilicide.

In the pixel circuit section 1 and resistor forming region where the protective film 240 is left in Stage F-1, the silicide layer is not formed because the protective film 240 keeps the metal film 250 from coming in contact with the silicon substrate 100 or the gate electrodes. The protective film 240 thus functions as a silicide block. A silicide layer can be a cause of noise in the pixel circuit section 1. It is therefore desirable that no silicide layer be formed in the pixel circuit section 1, particularly in the light-receiving region 101, the detection region 103, and the source/drain regions 104 and 105 of the amplifying element 15. Also, if a silicide layer is formed in the resistor forming region, the resistance is excessively reduced. It is therefore advantageous to protect the resistor forming region with the protective film 240. Although the protective film 240 may be removed after the formation of the silicide layers 132, 133, 134 and 135, the protective film 240 is left to avoid undesired damage to the pixel circuit 10.

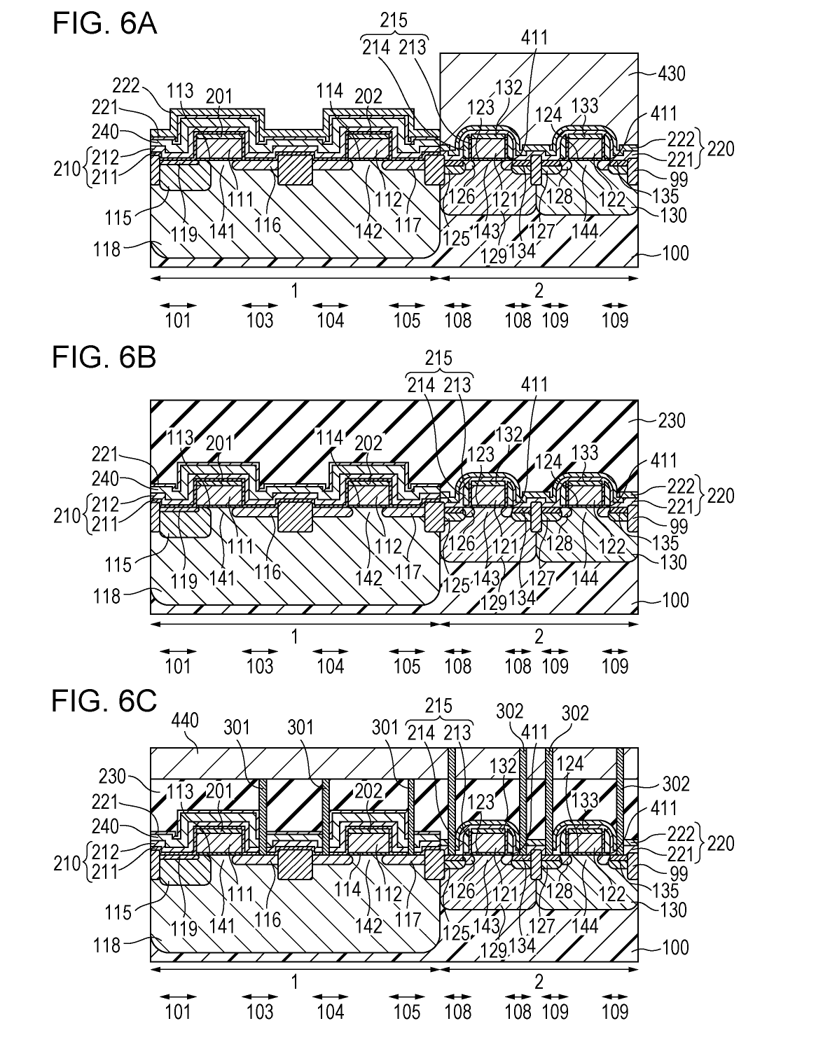

Step G will be described with reference to FIG. 6A. In Step G, a second insulator film 220 will be formed as shown in FIG. 6A. The second insulator film 220 covers the upper surfaces of the gate electrodes 111, 112, 121 and 122, side wall spacers 215, and the source/drain regions 108 and 109. The second insulator film 220 also covers the first insulator film 210 in the pixel circuit section 1.

The second insulator film 220 has a multilayer structure including a second silicon oxide layer 221 and a second silicon nitride layer 222. The second silicon nitride layer 222 is formed so as to come in contact with the second silicon oxide layer 221. The formation of the second insulator film 220 includes Stage G-1 of forming the second silicon oxide layer 221 by thermal CVD, and Stage G-2 of forming the second silicon nitride layer 222 by plasma CVD. Desirably, the second silicon nitride layer 222 is formed to a larger thickness than the second silicon oxide layer formed in the previous Stage G-1. The thickness of the second silicon nitride layer 222 may be twice or more that of the second silicon oxide layer 221. The thickness of the second silicon oxide layer 221 may be in the range of 10 nm to 40 nm. The thickness of the second silicon nitride layer 222 may be in the range of 30 nm to 100 nm. In Stage G-1, the second silicon oxide layer 221 is formed by, for example, thermal CVD under condition where the pressure (forming pressure) of the process gas containing tetraethoxysilane (TEOS) or the like as the source gas is in the range of 200 Pa to 600 Pa (what is called sub-atmospheric CVD (SA-CVD)). The deposition temperature (substrate temperature) at this time is, for example, in the range of 400° C. to 500° C. Thus, both the first silicon oxide layer 211 and the second silicon oxide layer 221 are formed by thermal CVD. It is however advantageous to perform the thermal CVD for forming the second silicon oxide layer 221 at a higher process gas pressure than the thermal CVD for forming the first silicon oxide layer 211. It is also advantageous to perform the thermal CVD for forming the second silicon oxide layer 221 at a lower deposition temperature than the thermal CVD for forming the first silicon oxide layer 211. These CVD conditions help the second silicon oxide layer 221 fill the gaps 401 satisfactorily.

In Stage G-2, the second silicon nitride layer 222 is formed by plasma CVD using a process gas containing, for example, SiH₄ and NH₃ as the source gas. The RF power of the plasma at this time is, for example, in the range of 100 W to 300 W. The deposition temperature (substrate temperature) at this time is, for example, in the range of 350° C. to 450° C. The total pressure of the process gas at this time is, for example, in the range of 30 Pa to 500 Pa.

The second silicon nitride layer 222 functions as hydrogen supplier that can constantly supply hydrogen to the peripheral transistors. The thick second silicon nitride layer 222 can be rich in hydrogen, and the thin second silicon oxide layer 221 allows appropriate permeation of hydrogen.

The second silicon nitride layer 222 also functions as a hydrogen permeable film that is permeable to hydrogen in a hydrogen annealing process described later. Thus, MOSFETs superior in noise properties can be formed. The second silicon oxide layer 221 underlying the second silicon nitride layer 222 is permeable to hydrogen, and is thus unlikely to interfere with hydrogen supply to the first conductivity type (n-type) and the second conductivity type (p-type) MOSFETs.

The portion of the second silicon oxide layer 221 in the pixel circuit section 1 and the portion of the second silicon oxide layer 221 in the peripheral circuit section 2 can be formed in the same process step. This can reduce the number of steps. The thermal CVD for forming the second silicon oxide layer 221 helps the second silicon oxide layer 221 fill the gaps 401 between the side wall spacers 215 and the source/drain regions 108 and 109. Thus, a reliable semiconductor can be manufactured.

Step H will be described with reference to FIGS. 6A and 6B. In Step H, a third insulator film 230 will be formed.

In Stage H-1, a resist 430 is formed to cover the portion of the second insulator film 220 in the peripheral circuit section 2, as shown in FIG. 6A. In subsequent Stage H-2, the second silicon nitride layer 222 of the second insulator film 220 is removed from the pixel circuit section 1 by etching using the resist 430 as a mask. The portion of the second silicon nitride layer 222 in the pixel circuit section 1 overlies the photoelectric conversion element 11, the transfer element 12, the capacitor 13, the amplifying element 15, the reset element 16, and the selection element 17. In this stage, the second silicon oxide layer 221 functions as an etching stopper for removing the second silicon nitride layer 222 from the pixel circuit section 1 by etching. The second silicon oxide layer 221 also acts as a protective layer for protecting the pixel circuit section 1 from damage.

In subsequent Stage H-3, a third insulator film 230 is formed so as to cover the pixel circuit section 1 and the peripheral circuit section 2, as shown in FIG. 6B. The third insulator film 230 is a monolayer silicon oxide film formed by plasma CVD such as high-density plasma CVD (HDP-CVD). The third insulator film 230 can be formed of BPSG, BSG, PSG or the like, and may be a multilayer film.

In subsequent Stage H-4, the third insulator film 230 is planarized. FIG. 6B shows the state after Stage H-4. For planarizing the third insulator film, chemical mechanical polishing (CMP), a reflow process or an etch back process, or combination of these processes may be applied. The thickness of the third insulator film 230 before the planarization is, for example, in the range of 200 nm to 1700 nm. The thickness of the third insulator film 230 after the planarization can be larger than the thicknesses of the first insulator film 210 and the second insulator film 220. In the present embodiment, since the second silicon nitride layer 222 is removed from the pixel circuit section 1, the difference in height between the peripheral circuit section 1 and the peripheral circuit section 2 is small under the third insulator film 230. Accordingly, the thickness of the third insulator film 230 after planarization can be as small as 1000 nm or less (for example, in the range of 450 nm to 850 nm). This is advantageous in reducing resistance and increasing sensitivity.

Step I will be described with reference to FIG. 6C. In Step I, conductor members 312 connected to the source/drain regions 108 or 109 through the second insulator film 220 will be formed, as shown in FIGS. 2A and 2B. Also, conductor members 311 connected to the source/drain regions of the pixel circuit section 1 through the first insulator film 210 will be formed. In addition, conductor members 313 connected, one each, to the gate electrodes 111, 112, 126 and 127, and conductor members 314 connected, one each, to the gate electrodes 121 and 122 are formed.

In Stage I-1, contact holes 301 for forming the conductor members 311 are formed in the third insulator film 230 by anisotropic dry etching using a resist covering the third insulator film 230. For forming the portion of the contact holes 301 passing through the third insulator film 230 in the pixel circuit section 1, it is advantageous to use the first silicon nitride layer 212 of the first insulator film 210 as an etching stopper. The contact holes 301 are formed to pass through the third insulator film 230, the second silicon oxide layer 221, the protective film 240, the first silicon nitride layer 212, and the first silicon oxide layer 211. Then, the contact holes 301 expose the source/drain regions of the capacitor 13, the amplifying element 15, the reset element 16 and the selection element 17, and the reference contact region therein. The contact holes exposing the gate electrodes of the capacitor 13, the amplifying element 15, the reset element 16 and the selection element 17 are formed at the same time as the formation of the contact holes 301. Similarly, the contact holes (not shown) for forming the conductor members 313 are also formed to pass through the third insulator film 230, the second silicon oxide layer 221, the protective film 240, the first silicon nitride layer 212, and the first silicon oxide layer 211. The contact holes (not shown) for forming the conductor members 313 pass through the insulator members 201 and 202 further. In order to reduce the contact resistance of the contact plugs, the impurity regions of the silicon substrate may be doped through the contact holes. In Stage H-2, the second silicon nitride layer 222 has been removed from the pixel circuit section 1, as described above. Thus, there is no silicon nitride layer over the first silicon nitride layer 212 used as an etching stopper. When the contact holes 301 are formed, therefore, the formation of the contact holes is not interrupted by the silicon nitride layer.

In subsequent Stage I-2, holes are formed in the third insulator film 230 by anisotropic dry etching using a resist 440 covering the third insulator film 230 and contact holes 301. Thus contact holes 302 for forming the conductor members 312 and 314 are formed. For forming the portion of the contact holes 302 passing through the third insulator film 230 in the peripheral circuit section 2, it is advantageous to use the second silicon nitride layer 222 of the second insulator film 220 as an etching stopper. The contact holes 302 are formed to pass through the third insulator film 230, the second silicon nitride layer 222, and the second silicon oxide layer 221. Then, the contact holes 302 expose the silicide layers 134 and 135 in the source/drain regions 108 and 109 of the peripheral transistors. Contact holes (not shown) exposing the silicide layers 132 and 133 of the gate electrodes 121 and 122 are formed for forming the conductor members 314 at the same time as the formation of the contact holes 302.

In subsequent Stage I-3, the contact holes 301, 302 are filled with a conductive material to form conductor members 311, 312, 313 and 314 as contact plugs, respectively. The contact holes 301 and 302 can be simultaneously filled with the conductive material.

In the present embodiment, the step of forming the conductor members includes Stage I-1 of forming the contact holes 301 and 303 in the pixel circuit section 1 and Stage I-2 of forming contact holes 302 and 304 in the peripheral circuit section 2, and these two stages are performed at different timings. Thus, the impurity regions of the pixel circuit section 1 are prevented from being contaminated with the metal of the silicide layers 132, 133, 134 and 135 through the contact holes 301 and 303. The order of Stages I-1 and 1-2 may be reversed. Contact holes 302 and 304 may be formed after filling contact holes 301 and 303 to form the conductor members 311 and 313. Alternatively, contact holes 301, 302, 303 and 304 may be formed at one time.

Thus the structure shown in FIGS. 2A and 2B is formed. Then, metal conductive lines, color filters, microlenses and other members are formed to complete an image sensing device. In the state where the peripheral transistors are covered with the second insulator film 220, hydrogen annealing may be performed for promoting the hydrogen supply to the MOSFETs. Hydrogen annealing refers to termination of the molecules at the surface of the silicon substrate 100 performed by heating the silicon substrate 100 in a hydrogen atmosphere. Desirably, hydrogen annealing is performed after the conductor members 311, 312, 313 and 314, and further the metal conductive lines, are formed. The second silicon nitride layer 222 formed by plasma CVD is permeable to hydrogen and helps supply hydrogen to the silicon substrate 100. Also, the hydrogen in the second silicon nitride layer 222 can be supplied to the surface of the silicon substrate 100 by heating the silicon substrate 100 even in an atmosphere not containing hydrogen.

An image sensing device has been described as an embodiment of the semiconductor device according to the present application. The features of the application can be applied to other semiconductor devices including insulated-gate field-effect transistors, such as arithmetical units, memory devices, control units, signal processing units, detectors, and display devices.

Embodiments of the present application can provide reliable semiconductor devices.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-251386, file Dec. 4, 2013, which is hereby incorporated by reference herein in its entirety.

What is claimed is:

1. A method for manufacturing a semiconductor device including an insulated-gate field-effect transistor, the method comprising:
a first step of forming a side wall spacer covering a side surface of a gate electrode of the transistor by forming a first insulator film covering an upper and a side surface of the gate electrode and a source/drain region of the transistor, and etching the first insulator film;
a second step of forming a silicide layer on the source/drain region; and
a third step of forming a second insulator film including a silicon oxide layer and a silicon nitride layer so as to cover the side wall spacer and the silicide layer,
wherein the third step includes forming the silicon oxide layer by thermal CVD so as to come in contact with the side wall spacers, and forming the silicon nitride layer by plasma CVD so as to come in contact with the silicon oxide layer.

2. The method according to claim 1, wherein the thermal CVD is performed at a process gas pressure in the range of 200 Pa to 600 Pa.

3. The method according to claim 1, wherein the silicon oxide layer is formed so as to fill a gap between the side wall spacer and the silicon substrate.

4. The method according to claim 1, wherein the silicon substrate is provided with a peripheral circuit section including the transistor and a pixel circuit section including a photoelectric conversion element having a light-receiving region, and wherein the first insulator film is formed so as to cover the light-receiving region, and the side wall spacer is formed so that the first insulator film remains over the light-receiving region.

5. The method according to claim 4, wherein the pixel circuit section includes an amplifying element including a channel region and configured to generate a signal according to charges generated in the photoelectric conversion element, and wherein the first insulator film is formed so as to cover the channel region of the amplifying element, and the side wall spacer is formed so that the first insulator film remains over the channel region.

6. The method according to claim 1, wherein a silicide layer is further formed on the upper surface of the gate electrode in the second step.

7. The method according to claim 1, wherein the second step includes: forming a protective film covering the source/drain region; etching the protective film so as to remove a portion thereof overlying the source/drain region and leave the portion thereof overlying other region than the source/drain region; and forming a metal film covering the source/drain region and the remaining protective film; and reacting the metal film with the source/drain region, thereby forming the silicide layer.

8. The method according to claim 7, further comprising: forming a lightly doped impurity region in the source/drain region before the first step; and forming a heavily doped impurity region having a higher impurity concentration than the lightly doped impurity region in the source/drain region and the other region between the first step and the second step.

9. The method according to claim 7, wherein a resistive element lies in the other region than the source/drain region under the protective film.

10. The method according to claim 1, wherein the first insulator film is a multilayer film including a silicon oxide layer and a silicon nitride layer, and wherein the first step includes: forming the silicon oxide layer of the first insulator film by thermal CVD; and forming the silicon nitride layer of the first insulator film by plasma CVD so as to come in contact with the silicon oxide layer of the first insulator film.

11. The method according to claim 10, wherein a process gas pressure of the thermal CVD for forming the silicon oxide layer of the second insulator film is higher than a process gas pressure of the thermal CVD for forming the silicon oxide layer of the first insulator film.

12. The method according to claim 1, further comprising a fourth step of forming conductor member connected to the source/drain region penetrating through the second insulator film.

13. The method according to claim 12, wherein the fourth step includes: forming a third insulator film covering the second insulator film and a contact hole above the source/drain region in the third insulator film, and wherein when the contact hole is formed in the third insulator film, the second insulator film is used as an etching stopper.

14. The method according to claim 13, wherein the fourth step further includes planarizing the third insulator film.

15. The method according to claim 13, wherein the silicon substrate is provided with a peripheral circuit section including the transistor and a pixel circuit section including a photoelectric conversion element having a light-receiving region and a reset element covered with the first insulator film and configured to reset the photoelectric conversion element, and wherein the forth step further includes: removing a portion of the silicon nitride layer of the second insulator film overlying the reset element, and forming contact hole in the first insulator film and the third insulator film right above a impurity region of the reset element, using the first insulator film as an etching stopper.

16. The method according to claim 15, wherein the contact hole above the impurity region of the reset element and the contact hole above the source/drain region are formed at different timings.

17. The method according to claim 1, further comprising the step of heating the silicon substrate in a hydrogen atmosphere with the transistor covered with the second insulator film after the third step.

18. The method according to claim 7, wherein the silicon substrate is provided with a peripheral circuit section including the transistor and a pixel circuit section including a photoelectric conversion element having a light-receiving region, and wherein the photoelectric conversion element lies in the other region than the source/drain region under the protective film.

19. The method according to claim 18, wherein the first insulator film is formed so as to cover the light-receiving region, and the side wall spacer are formed so that the first insulator film remains over the light-receiving region, and wherein the third step is performed so that the protective film remains over the first insulator film remaining over the light-receiving region.

20. The method according to claim 7, wherein the silicon substrate is provided with a peripheral circuit section including the transistor and a pixel circuit section including a photoelectric conversion element having a light-receiving region, and wherein an amplifying element configured to generate signal according to charges generated in the photoelectric conversion element lies in the specific region under the protective film.
